(19) United States
(12) Patent Application Publication
(10) Pub. No.: US 2008/0149971 A1
(43) Pub. Date: Jun. 26, 2008

(54) SEMICONDUCTOR DEVICE AND METHOD FOR FABRICATING THE SAME

(76) Inventor: Eunjong SHIN, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/944,655

(22) Filed: Nov. 26, 2007

(30) Foreign Application Priority Data
Dec. 26, 2006 (KR) 10-2006-0133471

(51) Int. Cl. H01L 21/336; H01L 29/78

(52) U.S. Cl. 257/288; 438/303; 257/E21.409; 257/E29.255

(57) ABSTRACT

A method for fabricating a semiconductor device is provided. The method includes forming a gate insulating layer on a semiconductor substrate, forming a gate electrode on the gate insulating layer, forming spacers on sidewalls of the gate electrode, forming impurity regions in the semiconductor substrate using the gate electrode and the spacers as masks, forming a capping layer over the semiconductor substrate to cover the gate electrode and the impurity regions, the capping layer having a compressive stress, and implanting impurity ions to portions of the capping layer corresponding to the impurity regions, such that the portions of the capping layer have a local tensile stress.

This application claims the benefit of priority to Korean Patent Application No. 10-2006-0133471, filed Dec. 26, 2006, the entire contents of which are incorporated herewith by reference.

### BACKGROUND

1. Technical Field

The present invention relates, in general, to a semiconductor device and a method for fabricating the same and, more particularly, to a semiconductor device and a method for fabricating the same, capable of controlling stress on a channel region of the semiconductor device.

2. Related Art

Semiconductor devices, such as an N-type metal-oxide-semiconductor field effect transistor (N-MOSFET), may have an increased electron mobility when a channel region of the N-MOSFET experiences a local tensile stress. On the other hand, semiconductor devices, such as a P-type metal-oxide-semiconductor field effect transistor (P-MOSFET), may have an increased hole mobility when a channel region of the P-MOSFET experiences a local compressive stress. The increase of electron or hole mobility may enhance the operating speed of the semiconductor devices.

Such stresses on the channel regions of the N-MOSFET and the P-MOSFET may be controlled by forming a capping layer, made of silicon nitride (SiN), to cover a gate electrode formed on a semiconductor substrate. The capping layer may be used as an etch-stop layer when forming contact holes.

However, since the semiconductor device often includes both the N-MOSFET and the P-MOSFET, the stresses on the channel regions of the N-MOSFET and the P-MOSFET may be controlled by the capping layer formed on the N-MOSFET or the P-MOSFET. In general, the stresses are controlled on the basis of the N-MOSFET.

Referring now to FIGS. 1A to 1C, there are shown cross-sectional views illustrating a method for fabricating a conventional semiconductor device.

To form trenches 23, as shown in FIG. 1A, a pad oxide layer (not shown) and a pad nitride layer (not shown) may be sequentially formed over a semiconductor substrate 11. The pad oxide layer and the pad nitride layer may be patterned by using a photolithography method, so as to expose portions of semiconductor substrate 11. The exposed portions of semiconductor substrate 11 may be etched by using the pad oxide layer as a mask, thus forming trenches 23.

An insulating layer, such as a silicon oxide layer, may be deposited on the pad nitride layer by a chemical vapor deposition (CVD) method, such that trenches 23 are filled with an insulating material. The insulating layer may be polished by a chemical mechanical polishing (CMP) method, thus forming isolation layers 25. The pad nitride layer and the pad oxide layer may then be removed by wet etching.

As shown in FIG. 1A, a gate oxide layer 13 is formed on semiconductor substrate 11 through thermal oxidization. Polycrystalline silicon, for example, may be deposited on gate oxide layer 13, and then patterned by a photolithography method, so that semiconductor substrate 11 is exposed, thus forming a gate electrode 15.

Referring to FIG. 1B, spacers 17 are formed on sidewalls of gate electrode 15. Impurity ions having a conductive type opposite to that of semiconductor substrate 11 may be doped in the semiconductor substrate 11 using gate electrode 15 and spacers 17 as masks, thus forming impurity regions 19 to be used as source and drain regions.

Referring to FIG. 1C, silicon nitride (SiN), for example, may be deposited on semiconductor substrate 11 to cover gate electrode 15 by using a plasma-enhanced (PE) CVD method, thus forming a capping layer 21 on gate electrode 15 and on the exposed portions of semiconductor substrate 11. Capping layer 21 may be used as an etch-stop layer when contact holes are formed.

The silicon nitride (SiN), which is deposited by the PECVD method and constitutes capping layer 21, undergoes a compressive stress. Thus, since impurity regions 19 contacting capping layer 21 also undergo a compressive stress, and a channel region formed between impurity regions 19 experiences a local tensile stress.

As described above, in the prior art, capping layer 21 is deposited by a PECVD method in such a way to undergo a compressive stress, and impurity regions 19 also experience a compressive stress. Thus, the channel region undergoes a tensile stress. Accordingly, the electron mobility of the semiconductor device can be increased.

As mentioned earlier, in the prior art, the channel region is made to undergo tensile stress so as to increase the electron mobility. Therefore, the operating speed of a N-MOSFET can be increased. However, there are problems in that the hole mobility is lowered and the operating speed of a P-MOSFET is decreased because the operating speed of the N-MOSFET is increased.

### SUMMARY

Embodiments consistent with the present invention provide a semiconductor device and a method for fabricating the semiconductor, in which the operating speed of a P-MOSFET in the semiconductor device can be increased without decreasing the operating speed of a N-MOSFET in the semiconductor device.

In one embodiment, there is provided a method for fabricating a semiconductor device, including forming a gate insulating layer on a semiconductor substrate, forming a gate electrode on the gate insulating layer, forming spacers on sidewalls of the gate electrode, forming impurity regions in the semiconductor substrate using the gate electrode and the spacers as masks, forming a capping layer over the semiconductor substrate to cover the gate electrode and the impurity regions, the capping layer having a compressive stress, and implanting impurity ions to portions of the capping layer corresponding to the impurity regions, such that the portions of the capping layer have a local tensile stress.

In another embodiment, there is provided a semiconductor device including a semiconductor substrate, a gate insulating layer formed on the semiconductor substrate, a gate electrode formed on the gate insulating layer, spacers formed on sidewalls of the gate electrode, impurity regions formed in the semiconductor substrate, a capping layer formed over the semiconductor substrate covering the gate electrode and the impurity regions, wherein portions of the capping layer corresponding to the impurity regions comprises impurity ions implanted therein, such that the portions of the capping layer have a local tensile stress.

### BRIEF DESCRIPTION OF THE DRAWINGS

The above and other features consistent with the present invention will become apparent from the following detailed description given in conjunction with the accompanying drawings, in which:

FIGS. 1A to 1C are cross-sectional views illustrating a method for fabricating a conventional semiconductor device; and

FIGS. 2A to 2D are cross-sectional views illustrating a method for fabricating a semiconductor device in accordance with an embodiment consistent with the present invention.

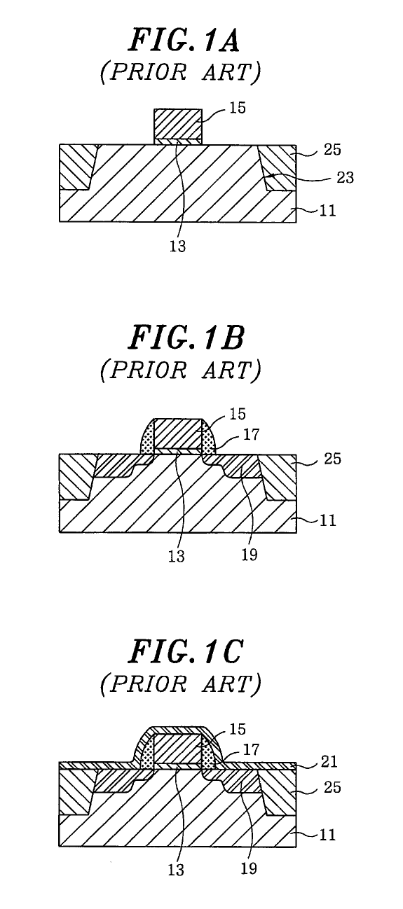

### DETAILED DESCRIPTION

Hereinafter, embodiments consistent with the present invention will be described in detail with reference to the accompanying drawings so that they can be readily implemented by those skilled in the art.

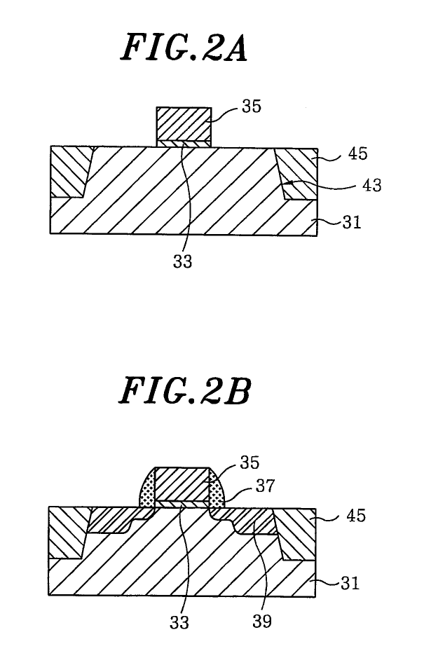

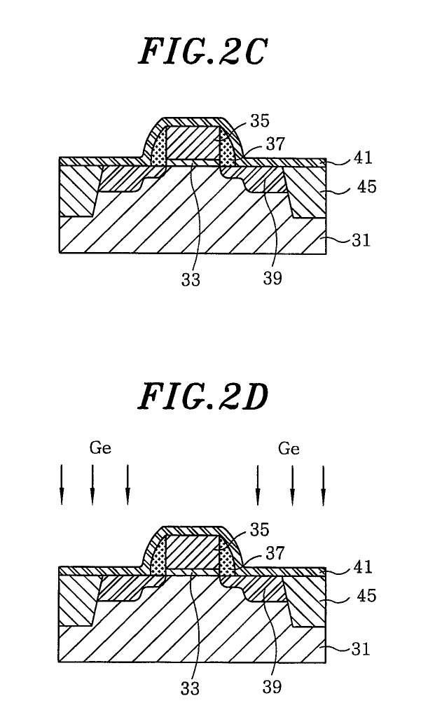

Referring first to FIG. 2A, a pad oxide layer (not shown) and a pad nitride layer (not shown) may be sequentially formed over a semiconductor substrate 31. A photoresist may be coated on the pad nitride layer, and then exposed and developed to form a photoresist pattern. The pad nitride layer and the pad oxide layer may be patterned by using the photoresist pattern as an etch mask, so as to expose portions of semiconductor substrate 31.

Then, the photoresist pattern is removed, and the exposed portions of semiconductor substrate 31 may be etched by using the pad oxide layer as a mask, thus forming trenches 43.

A insulating layer comprising, for example, silicon oxide, boro-phospho silicate glass (BPSG), undoped silicate glass (USG), phospho-silicate glass (PSG), boro-silicate glass (BSG), fluorine doped silicate glass (FSG), or tetra ethyl ortho silicate (TEOS), may be deposited on the pad nitride layer by a CVD method, so that trenches 43 are filled with insulating materials. The insulating layer may be polished by a CMP method using the pad nitride layer as an etch-stop layer, thus forming isolation layers 45. The pad nitride layer and the pad oxide layer are then removed by wet etch.

As shown in FIG. 2A, a gate oxide layer 33 is formed on semiconductor substrate 31 by using, for example, a thermal oxidization process. Conductive material, such as polycrystalline silicon or a conductive metal, is may be deposited on gate oxide layer 33 by using a CVD method or a physical vapor deposition (PVD) method.

A photoresist may be coated on the deposited conductive material, and then exposed and developed to form a photoresist pattern (not shown). The deposited conductive material patterned by using the photoresist pattern as a mask, such that semiconductor substrate 31 is exposed, thus forming a gate electrode 35. The photoresist pattern is then removed.

Referring to FIG. 2B, an insulating material, such as silicon oxide or TEOS (tetraethyl orthosilicate), may be deposited over semiconductor substrate 31 by using a CVD method. The insulating material may be etched back by using, for example, a reactive ion etching (RIE) method, so that semiconductor substrate 31 is exposed, thus forming spacers 37 on sidewalls of gate electrode 35.

Impurity ions having a conductive type opposite to that of semiconductor substrate 31 may then be implanted into semiconductor substrate 31 by using gate electrode 35 and spacers 37 as masks, thus forming impurity regions 39 used as source and drain regions.

Referring to FIG. 2C, silicon nitride (SiN), for example, may be deposited over semiconductor substrate 31 by using a PECVD method, in such a way to cover gate electrode 35 and spacers 37, thus forming a capping layer 41, which may be used as an etch-stop layer when contact holes are formed.

The silicon nitride (SiN), which is deposited by the PECVD method and constitutes capping layer 41, has a compressive stress. Thus, a portion of impurity regions 39 contacting capping layer 41 also have a compressive stress. Accordingly, a channel region between impurity regions 19 of semiconductor substrate 31 has a local tensile stress.

Because the channel region has a local tensile stress, the electron mobility in the channel region is increased. Thus, operating characteristics of an N-MOSFET may be improved. However, because the hole mobility in the channel region is decreased, operating characteristics of a P-MOSFET may be degraded.

In order to prevent this problem, impurity ions may be selectively implanted into portions of capping layer 41 corresponding to impurity regions 39 of the P-MOSFET, as shown in FIG. 2D, so that the portions of capping layer 41 may have a local tensile stress. In one embodiment, a material having four valence bonds, such as germanium (Ge), may be implanted into the portions of capping layer 41 corresponding to impurity regions 39 at a dosage of about 1×10¹⁴ to 1×10¹⁵. At this time, the implanted germanium (Ge) is located between particles of capping layer 41. Accordingly, capping layer 41 may have a local tensile stress.

Therefore, impurity regions 39 contacting the portions of capping layer 41 having a local tensile stress also have a local tensile stress. Consequently, the channel region between impurity regions 39 may have a compressive stress, thereby increasing the hole mobility in the channel region.

Because the hole mobility is increased in the channel region, operating characteristics of the P-MOSFET can be improved.

As described above, capping layer 41 comprising SiN may be formed to cover gate electrode 35 using the PECVD method, so that it has a compressive stress. Thus, the channel region may have a tensile stress, and the electron mobility in the channel region can be improved. Further, Ge may be selectively implanted into the portions of capping layer 41 corresponding to impurity regions 39 of the P-MOSFET, so that it has a local tensile stress. Therefore, impurity regions 39 may also have a local tensile stress. Consequently, the channel region between impurity regions 39 may have a compressive stress, and the hole mobility in the channel region can be increased.

As described above, only the channel region of the P-MOSFET has a compressive stress. Accordingly, the operating speed of a P-MOSFET can be increased without decreasing the operating speed of a N-MOSFET.

While the invention has been described with respect to specific embodiments, it will be understood by those skilled in the art that various changes and modifications may be made without departing from the scope consistent with the invention as defined in the appended claims.

What is claimed is:

1. A method for fabricating a semiconductor device, comprising:
forming a gate insulating layer on a semiconductor substrate;
forming a gate electrode on the gate insulating layer;
forming spacers on sidewalls of the gate electrode;
forming impurity regions in the semiconductor substrate using the gate electrode and the spacers as masks;
forming a capping layer over the semiconductor substrate to cover the gate electrode and the impurity regions, the capping layer having a compressive stress; and
implanting impurity ions to portions of the capping layer corresponding to the impurity regions, such that the portions of the capping layer have a local tensile stress.

2. The method of claim 1, wherein forming the capping layer comprises depositing SiN over the semiconductor substrate by using a plasma-enhanced chemical vapor deposition (PECVD) method.

3. The method of claim 1, wherein the impurity ions includes a material having four valence bonds.

4. The method of claim 3, wherein the material having four valence bonds comprises germanium (Ge).

5. The method of claim 3, wherein the impurity ions are implanted at a dosage of about 1×10¹⁴ to 1×10¹⁵.

6. A semiconductor device comprising:
a semiconductor substrate;
a gate insulating layer formed on the semiconductor substrate;
a gate electrode formed on the gate insulating layer;
spacers formed on sidewalls of the gate electrode;
impurity regions formed in the semiconductor substrate;
a capping layer formed over the semiconductor substrate covering the gate electrode and the impurity regions, wherein portions of the capping layer corresponding to the impurity regions includes impurity ions implanted therein, such that the portions of the capping layer have a local tensile stress.

7. The semiconductor device of claim 6, wherein the capping layer comprises silicon nitride, and is formed by using a plasma-enhanced chemical vapor deposition (PECVD) method.

8. The semiconductor device of claim 6, wherein the impurity ions comprise a material having four valence bonds.

9. The semiconductor device of claim 8, wherein the material having four valence bonds comprises germanium (Ge).

10. The semiconductor device of claim 8, wherein the impurity ions are implanted at a dosage of about 1×10¹⁴ to 1×10¹⁵.
